(19) United States
(12) Patent Application Publication
(10) Pub. No.: US 2012/0299604 A1
(43) Pub. Date: Nov. 29, 2012

(54) Electric field sensor and implements comprising same

(75) Inventors: John L. Waugaman, Perrysburg, OH (US); James A. Kirkman, Oregon, OH (US)

(73) Assignee: INNOVAGIO CORP.

(21) Appl. No.: 13/134,082

(22) Filed: May 27, 2011

(51) Int. Cl. G01R 27/04

(52) U.S. Cl. 324/629

(57) ABSTRACT

A system has a battery serving as a DC voltage source for electrical equipment of the system, a sensor for sensing an electric field (e-field) generated by the DC voltage source, sensor signal processing circuitry connected to the sensor for receiving a sensor output signal therefrom, and an e-field indicating device coupled to the sensor signal processing circuitry for receiving a processed DC e-field signal therefrom. The sensor outputs the sensor output signal, which is dependent upon a distance between the sensor and the DC voltage source. The sensor signal processing circuitry derives a processed direct current (DC) e-field signal from the sensor output signal. The e-field indicating device outputs the e-field indicating signal in response to the processed DC e-field signal indicating that the e-field exceeds an e-field threshold level.

### FIELD OF THE DISCLOSURE

The disclosures made herein relate generally to electric field (e-field) sensing apparatuses, systems, and methods and, more particularly, to Apparatuses, systems, and methods for detecting electric fields generated by a direct current (DC) voltage source.

### BACKGROUND

In any number of applications, high DC voltage is utilized for powering certain system components and/or for carrying out power transmission between a power generation location and one or more locations where such power is utilized. Examples of such applications include, but are not limited to, fully electric and/or hybrid electric vehicles, utility company power transmission, solar panel arrays, vehicles in public transportation systems, and the like.

It is not uncommon for DC voltage in certain applications (e.g., those mentioned above) to be provided at a level that can pose a significant risk to human safety. A person can unknowingly come into contact with high DC voltage such as due to malfunction or damage to equipment that stores, generates, and/or utilizes such high DC voltage. When a person does come into contact with such high DC voltage, the resulting DC current can be fatal or result in severe injury to the person.

Therefore, an approach for reliably and effectively detecting electric fields generated by a DC voltage source separately or in combination with electric fields generated by alternating current (AC) voltage source would be advantageous, desirable and/or useful.

### SUMMARY OF THE DISCLOSURE

Embodiments of the present invention relate to detecting electric fields generated by a DC voltage source. In many applications, high DC voltage can be present and unknowingly present a hazardous condition for those who may come into close proximity to or contact with such high voltage. While DC power supplies are convenient and efficient, their capacity for causing harmful or fatal hazards is far greater than for AC power supplies of similar voltage levels. DC power supplies increase the potential for bodily harm or fatality in that the non-alternating nature of DC current causes muscle contraction without intermission, therefore not allowing the body to break free once caught. As such, the ability to detect electric fields generated by a high DC voltage source provides a means for safely allowing persons to approach and work within environments/situations where there is the potential to come into contact with high DC voltage.

In one embodiment of the present invention, an apparatus comprises sensor signal processing circuitry having an input for receiving first and second sensor output signals from a sensor for sensing an e-field generated by a voltage source. The sensor signal processing circuitry outputs a processed AC e-field signal from the first and second sensor output signals when an AC e-field sensing mode of the sensor signal processing circuitry is enabled. The sensor signal processing circuitry outputs a processed DC e-field signal from the first and second sensor output signals when a DC e-field sensing mode of the sensor signal processing circuitry is enabled.

In another embodiment of the present invention, an apparatus comprises a sensor for sensing an e-field generated by a DC voltage source, sensor signal processing circuitry connected to the sensor for receiving a sensor output signal therefrom, and an e-field indicating device coupled to the sensor signal processing circuitry for receiving a processed DC e-field signal therefrom. The sensor outputs the sensor output signal that is dependent upon proximity of the sensor with respect to the DC voltage source. The sensor signal processing circuitry outputs the processed DC e-field signal from the sensor output signal. The e-field indicating device outputs an e-field indicating signal in response to the processed DC e-field signal indicating that the e-field exceeds an e-field threshold level.

In another embodiment of the present invention, an apparatus comprises a sensor for sensing an e-field generated by a voltage source, sensor signal processing circuitry connected to the sensor for receiving first and second sensor output signals therefrom, and an e-field indicating device coupled to the sensor signal processing circuitry for receiving a processed AC e-field signal and a processed DC e-field signal therefrom. The sensor outputs the first sensor output signal, which is dependent upon a distance between the sensor and the voltage source substantially irrespective of a direction the sensor is pointing with respect to the voltage source and simultaneously outputs the second sensor output signal, which is dependent upon the relative direction the sensor is pointing with respect to the voltage source. The sensor signal processing circuitry simultaneously outputs the processed AC e-field signal and a processed DC e-field signal from the first and second sensor output signals. The e-field indicating device outputs an e-field indicating signal in response to at least one of the processed AC e-field signal indicating that the e-field has an AC e-field portion that exceeds an AC e-field threshold level and the processed DC e-field signal indicating that the e-field has a DC e-field portion that exceeds a DC e-field threshold level.

In another embodiment of the present invention, a system comprises a battery serving as a DC voltage source for electrical equipment of the system, a sensor for sensing an e-field generated by the DC voltage source, sensor signal processing circuitry connected to the sensor for receiving a sensor output signal therefrom, and an e-field indicating device coupled to the sensor signal processing circuitry for receiving a processed DC e-field signal therefrom. The sensor outputs the sensor output signal, which is dependent upon a distance between the sensor and the DC voltage source. The sensor signal processing circuitry derives a processed DC e-field signal from the sensor output signal. The e-field indicating device outputs an e-field indicating signal in response to the processed DC e-field signal indicating that the e-field exceeds an e-field threshold level.

In another embodiment of the present invention, a method comprises a plurality of operations for providing information characterizing an e-field generated by a voltage source. An operation is carried out for sensing an e-field generated by a voltage source. The operation of sensing includes generating at least one e-field characterizing signal corresponding to the e-field. An operation is carried out for performing an AC e-field sensing mode of operation for deriving a processed AC e-field signal from at least one e-field characterizing signal. The processed AC e-field signal corresponds to an AC voltage level of the voltage source. An operation is carried out for performing a DC e-field sensing mode of operation for deriving a processed DC e-field signal from at least one e-field characterizing signal. The processed DC e-field signal corresponds to a DC voltage level of the voltage source.

These and other objects, embodiments, advantages and/or distinctions of the present invention will become readily apparent upon further review of the following specification, associated drawings and appended claims.

### BRIEF DESCRIPTION OF THE DRAWINGS

FIG. 1A is a perspective view showing a balanced field sensor configured in accordance with the present invention.

FIG. 1B is a cross-sectional view taken along the line 1B-1B in FIG. 1A.

FIG. 2 is a block diagram showing a DC e-field sensing apparatus configured in accordance with an embodiment of the present invention.

FIG. 3 is a block diagram showing an apparatus configured in accordance with an embodiment of the present invention for selectively switching between AC e-field sensing and DC e-field sensing.

FIG. 4 is a block diagram showing an apparatus configured in accordance with an embodiment of the present invention for simultaneous performing AC e-field sensing and DC e-field sensing.

FIG. 5 is a block diagram showing a system configured in accordance with an embodiment of the present invention for sensing presence of an e-field generated by a DC voltage source of the system.

### DETAILED DESCRIPTION OF THE DRAWING FIGURES

Embodiments of the present invention can be implemented in any number of configurations and for any number of applications. The underlying intent is to provide an indication as to whether an e-field generated by a voltage source may pose a risk. The voltage source can be an AC voltage source or a DC voltage source. In preferred embodiments of the present invention, the e-field of primary interest is that generated from a high DC voltage source. Such an e-field that is generated by high DC voltage is referred to herein as a HV DC e-field. High DC voltage in the context of the present invention generally refers to DC voltage of a level that is capable of causing bodily harm and/or fatality. In accordance with certain embodiments of the present invention, the indication of a HV DC e-field can be in the form of a visual signal and/or an audible signal (i.e., a field indicating signal). Furthermore, in accordance with certain embodiments of the present invention, the visual signal and/or the audible signal can be in the form of a qualitative form (e.g., safe/dangerous) and/or a quantitative form (e.g., a relative level or actual level of the e-field).

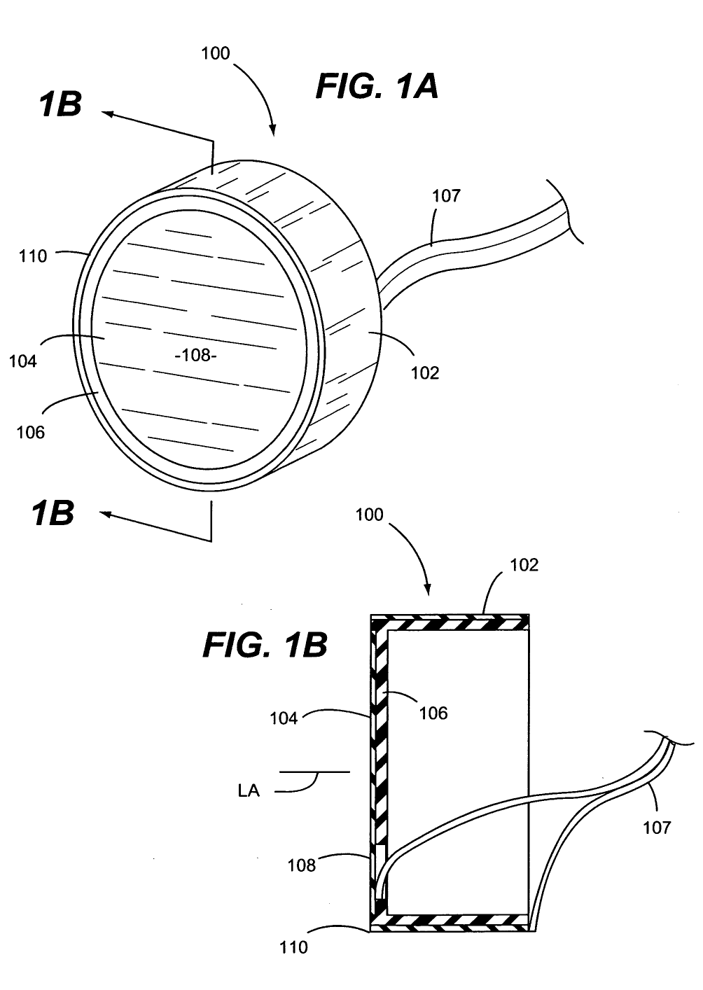

FIGS. 1A and 1B show a balanced e-field sensor (i.e., sensor 100) configured in accordance with an embodiment of the present invention. As will be discussed below in greater detail with respect to various field sensing circuitries, the balanced e-field sensor 100 is used within such circuitries for being electrically acted on by one or more e-fields (e.g., a DC e-field and/or AC e-field). Through such interaction with the e-field(s), the balanced e-field sensor 100 outputs a signal corresponding to the sensed e-field(s), which can be a signal that is proportional to the magnitude of the e-field at a location of the sensor 100. It is disclosed herein that the sensor 100 outputs a sensor output signal that is dependent upon proximity of the sensor 100 with respect to a voltage source of an e-field in which the sensor 100 is immersed.

The balanced e-field sensor 100 includes a tubular sensing element 102, a plate sensing element 104, an insulating material 106, and a signal lead 107. The tubular sensing element 102 and the plate sensing element 104 are each connected to a respective signal conductor of the signal lead 107. In the depicted embodiment, the tubular sensing element 102 is a cylindrically-shaped tube and the plate sensing element 104 is a round-shaped plate situated within the tubular sensing element 102. The insulating material 106 is situated between the tubular sensing element 102 and the plate sensing element 104, thereby inhibiting electrical conductivity therebetween (i.e., serves as an electrical insulator between the tubular sensing element 102 and the plate sensing element 104).

Preferably, as shown, flat sides 108 of the plate sensing element 104 extend approximately perpendicular to a centerline longitudinal axis LA of the tubular sensing element 102 and one of the flat sides 108 of the plate sensing element 104 is approximately flush with an end face 110 of the tubular sensing element 102. It is disclosed herein that the tubular sensing element 102 can have different cross sectional shape than cylindrical (e.g., a rectangular cross sectional shape), in which case, the plate sensing element 104 can have a corresponding shape (e.g., a rectangular shape). It is also disclosed herein that the tubular sensing element is an embodiment of a three-dimensional sensing element and that such three-dimensional sensing element can have a contiguously arcuate surface (e.g., a hemispherical shape).

When immersed in e-fields, the sensing elements 102, 104 each have induced a respective voltage in proportion to the strength of the e-fields. Advantageously, the balanced e-field sensor 100 can be used for sensing signals in both a non-directional (e.g., omnidirectional) manner and a directional manner. Using the balanced e-field sensor 100 for non-directional sensing includes connecting both the tubular sensing element 102 and the plate sensing element 104 together as one sensing antenna. Using the balanced e-field sensor 100 for directional sensing includes maintaining the signals from each of the sensing elements 102, 104 as individual signals and allowing downstream electronics to cancel unwanted portions of these signals. In this regard, e-fields impinging on both sensing elements 102, 104 will largely cancel each other and e-fields impinging primarily on the plate sensing element 104 will not be cancelled. Directional field sensing in a direction approximately along the centerline longitudinal axis LA is made possible via such field cancelling and such e-field impingement primarily on the plate sensing element 104. The e-field sensing signal produced solely by the tubular sensing element 102 provides for non-directional (e.g., omni-directional) e-field sensing. Non-directional e-field sensing can be useful in determining that a potentially dangerous voltage source is present and directional e-field sensing can be useful in determining where a source of the potentially dangerous voltage source is located.

In some applications, it will be desirable, if not necessary, for signals produced by the tubular sensing element 102 and the plate sensing element 104 to be equal when simultaneously exposed to the same e-field. This applies when the distance from the source of the field is much greater than any dimension of the sensor elements 102, 104 because the shape of each of the sensing elements 102, 104 at this distance is of less consequence than their respective areas. Accordingly, in one embodiment, such equal sensing element signal output is provided for by making the surface areas of the tubular sensing element 102 and the plate sensing element 104 approximately the same. In another embodiment, such equal sensing element signal output can be accomplished through the use of different signal gains (e.g., adjustable or fixed) to balance the sensing units 102, 104.

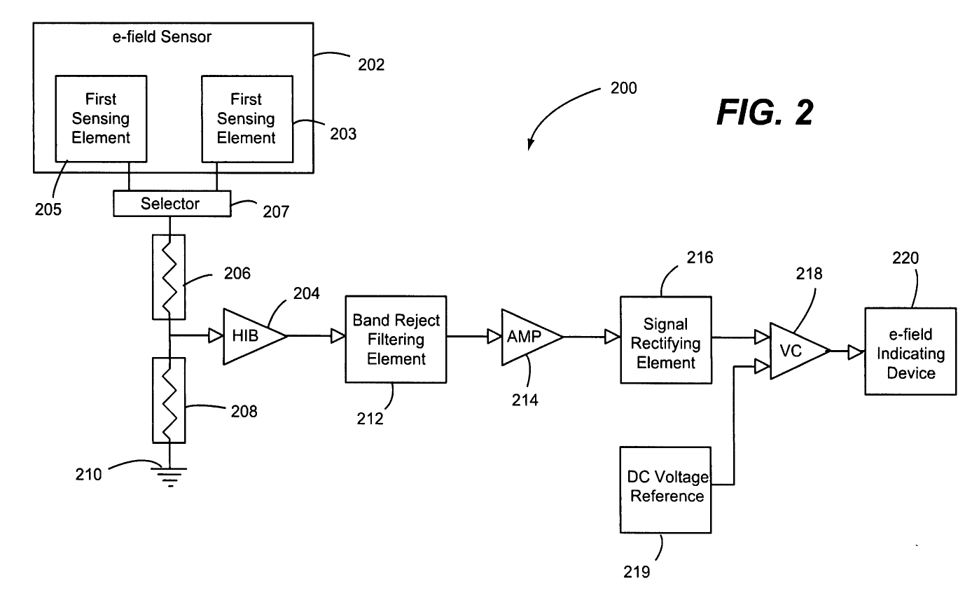

Referring now to FIG. 2, a block diagram of a DC e-field sensing apparatus 100 configured in accordance with an embodiment of the present invention is shown. Circuitry of the DC e-field sensing apparatus 200 provides an indication as to whether a DC e-field is present within proximity to the DC e-field sensing apparatus 200. The DC e-field sensing apparatus 200 is configured for indicating detection of only DC e-fields even though AC e-fields may also be present. Preferably, but not necessarily, the DC e-field sensing apparatus 200 is configured for sensing HV DC e-fields.

An e-field sensor 202 is acted on by an e-field when exposed to the e-field (i.e., immersed therein). The e-field sensor 202 can be configured in any number of different manners. In one embodiment, the e-field sensor 202 can be a plate sensing element. In another embodiment, the e-field sensor 202 can be a tubular sensing element. In still another embodiment, the e-field sensor 202 can be a balanced e-field sensor configured as disclosed above in reference to FIGS. 1A and 1B). In the case of a balanced e-field sensor, a first sensing element 203 and a second sensing element 205 can be selectively provided as the input signal to the DC e-field sensing apparatus 200 via a sensing element selector 207.

A high impedance buffer (HIB) 204 has its signal input connected between a first resistive element 206 and a second resistive element 208. The first resistive element 206 is connected between the e-field sensor 202 and the signal input of the HIB 204 and the second resistive element 208 is connected between the signal input of the HIB 204 and a circuit ground 210. The first resistive element 206 limits current applied to the HIB 204 in the event of electrostatic discharge. The second resistive element 208 develops voltage from charge placed on the e-field sensor 202 by an e-field in which the e-field sensor 202 is immersed.

The HIB 204 converts high impedance of the circuitry upstream of the HIB 204 to lower impedance required to drive circuitry downstream of the HIB 204. A HIB provides very low offset voltage drift with temperature which would otherwise appear as a DC field signal when amplified by the Difference Amplifiers. In a preferred embodiment, a chopper-stabilized operational amplifier is the device type used as a HIB.

A signal output of the HIB 204 is connected to a signal input of a band reject filtering element 212. The band reject filtering element 212 removes a specified AC signal component from the signal being processed. Thus, a band reject filtering element can be used as a type of an AC signal stripper. In one embodiment, the band reject filtering element 212 removes AC signals in a range of frequency including at least about 50-60 Hertz (e.g., as generated by e-fields from nearby AC power sources such as AC power transmission lines). A signal output of the band reject filtering element 212 is connected to a signal input of a signal amplifier (AMP) 214. The signal AMP 214 amplifies the DC e-field signal outputted from the band reject filtering element 212 for further processing.

A signal rectifying element 216 then converts the DC e-field signal from a DC polarity (i.e., positive or negative) to a unipolar DC e-field signal. The unipolar DC e-field signal is then provided via a signal output of the signal rectifying element 216 to a first signal input 218 of a voltage comparator (VC) 218. A DC voltage reference 219 is connected to a second signal input of the VC 218, thereby allowing a time/temperature stabilized threshold limit voltage to be provided to the VC 218. The VC 218 compares the unipolar DC e-field signal (i.e., the e-field derived signal from the signal rectifying element 216) to the DC reference voltage 219. At a signal output of the VC 218, unipolar DC e-field signals with a voltage that exceed the reference voltage cause output of an e-field indicating signal by an e-field indicating device 220. Signals at the signal output of the VC 218 are referred to herein as processed e-field signals (i.e., a processed DC e-field signal). Examples of alert signals by the e-field indicating device 220 include, but are not limited to, an audible alert signal, a visual alert signal, a tactile alert, an electric discrete/analog alert signal, an intelligent protocol communication signal wired or wireless or any combination of alert signals. Furthermore, the e-field indicating signal can be configured in a manner that indicates a relative magnitude of the sensed e-field. The components of the apparatus 200 that are connected between the sensor 202 and the e-field indicating device 220 are an embodiment of sensor signal processing circuitry configured in accordance with the present invention.

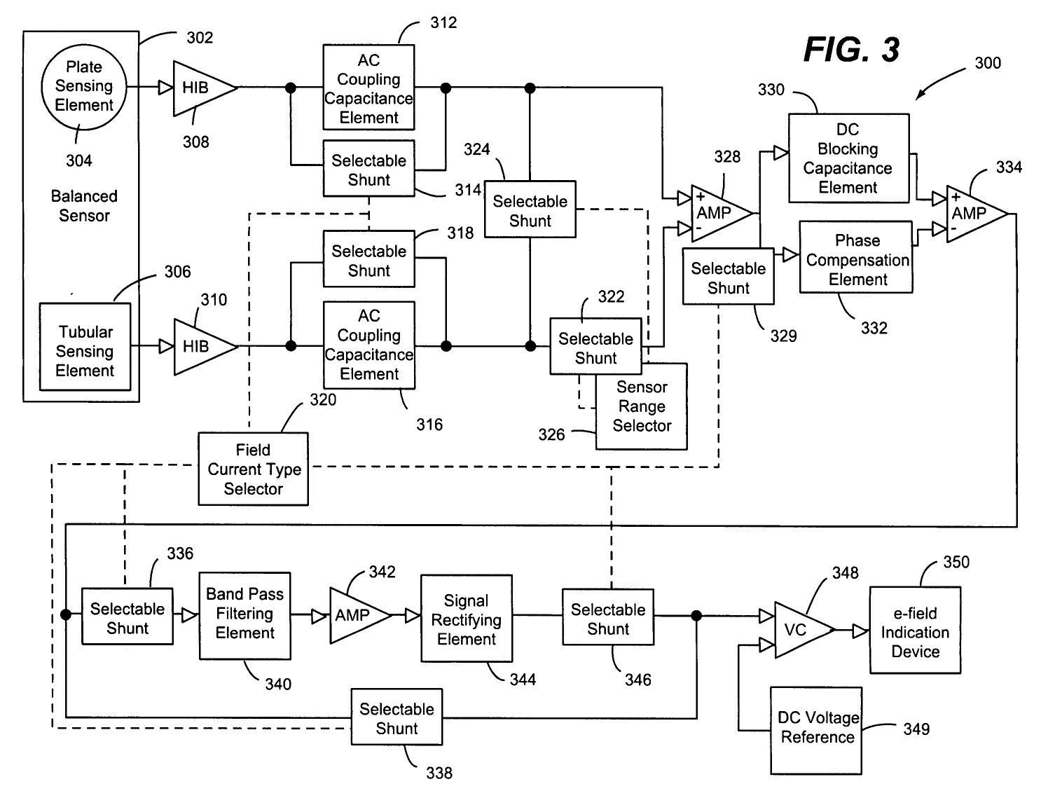

Referring now to FIG. 3, a block diagram of an apparatus configured in accordance with an embodiment of the present invention for selectively switching between AC e-field sensing and DC e-field sensing (i.e., switchable e-field sensing apparatus 300) is shown. Circuitry of the switchable e-field sensing apparatus 300 provides an indication as to whether an AC e-field or DC e-field of a given strength is present within proximity to the switchable e-field sensing apparatus 300. Preferably, but not necessarily, the switchable e-field sensing apparatus 300 is configured for sensing HV DC e-fields.

A balanced e-field sensor 302 is provided for sensing a DC e-field and/or an AC e-field when exposed thereto. The balanced e-field sensor 302 has a plate sensing element 304 and a tubular sensing element 306. In this regard, the balanced e-field sensor 302 is preferably, but not necessarily, of a similar construction of the same construction as that disclosed above in reference to the balanced e-field sensor 100 of FIGS. 1A and 1B. Accordingly, the balanced e-field sensor 302 is configured for coupling to an e-field toward the front of the plate sensing element 304, thereby providing for directional sensing of e-fields, and is configured for coupling to an e-field surrounding the tubular sensing element 306, thereby providing for non-directional sensing of e-fields.

A first high impedance buffer (HIB) 308 has its signal input connected to the plate sensing element 304 and a second high impedance buffer (HIB) 310 has its signal input connected the tubular sensing element 306. The first and second HIBs 308, 310 each convert high impedance of the balanced e-field sensor 302 to lower impedance required to drive circuitry downstream of the first and second HIBs 308, 310. It is disclosed herein that the signal input of the first and second HIBs 308, 310 can each be connected to the respective sensing element 304, 306 through a resistive element arrangement discussed above in reference to signal input of the HIB 204 in FIG. 2. To this end, it is disclosed herein that the sensing elements 304, 306 are each connected to the respective HIB 308, 310 in a manner that provides a required voltage characteristic at the respective HIB signal input.

A signal output of the first HIB 308 is connected to a first AC signal shunting arrangement and a signal output of the second HIB 310 is connected to a second AC signal shunting arrangement. The first AC signal shunting arrangement includes a first AC coupling capacitance element 312 and a first selectable shunt 314, which are connected in parallel with a signal output of the first HIB 308. The second AC signal shunting arrangement includes a second AC coupling capacitance element 316 and a second selectable shunt 318, which are connected in parallel with a signal output of the second HIB 310. The first and second selectable shunts 314, 318 allow a short circuit path across a respective one of the AC coupling capacitance elements 312, 316 to be selectively provided. When the first and second selectable shunts 314, 318 are in a condition where conductivity therethrough is inhibited (i.e., an AC field sensing mode), the AC coupling capacitance elements 312, 316 removes DC e-field signals appearing at the outputs of the respective one of the HIBs 308, 310. When the first and second selectable shunts 314, 318 are in a condition where conductivity therethrough is provided (i.e., a dual AC/DC field sensing mode), the AC coupling capacitance elements 312, 316 are bypassed such that both AC/DC e-field signals appearing at the outputs of the respective one of the HIBs 308, 310 are passed to the downstream transmission circuitry. The depicted embodiment of the field current type selecting arrangement includes a field current type selector 320 that allows the first and second selectable shunts 314, 318 to be selectively controlled for actuating the AC field sensing mode and the DC field sensing mode. In this regard, the field current type selector 320 is configured for causing the first and second selectable shunts 314, 318 to be selectively switched between a respective open configuration (i.e., conductivity therethrough is inhibited) and a respective closed configuration (i.e., conductivity therethrough is provided).

Through a third selectable shunt 322, a fourth selectable shunt 324, and a sensor range selector 326, the switchable e-field sensing apparatus 300 is configured for being selectively switchable between a mode for non-directional (e.g., omni-directional) e-field sensing and directional (e.g., a direction that the e-field sensing apparatus 300 is pointing). The third selectable shunt 322 is provide in series with an signal output of the second AC coupling capacitance element 316 and the fourth selectable shunt 324 is provided in parallel between the signal outputs of the first AC coupling capacitance element 312 and the second AC coupling capacitance element 316. As mentioned above, non-directional e-field sensing can be useful in determining that a potentially dangerous voltage source is present and directional e-field sensing can be useful in determining where a source of the potentially dangerous voltage source is located. Thus, the ability to selectively switch between such non-directional and directional e-field sensing modes is useful.

The sensor range selector 326 allows the third and fourth selectable shunts 322, 324 to be selectively controlled for causing the switchable e-field sensing apparatus 300 to be switched (e.g., manually switched) between its non-directional e-field sensing mode and its directional e-field sensing mode. When the sensor range selector 326 is configured for causing non-directional e-field sensing to be provided, the third selectable shunt 322 is in an open configuration and the fourth selectable shunt 324 is in a closed configuration. When the sensor range selector 326 is configured for causing directional e-field sensing to be provided, the third selectable shunt 322 is in a closed configuration and the fourth selectable shunt 324 is in an open configuration. As mentioned above, within the context of the present invention, a selectable shunt allows for conductivity therethrough when in its closed configuration and inhibits conductivity therethrough when in its open configuration.

The third and fourth selectable shunts 322, 324 are connected between the first and second selectable shunts 314, 318 and a first difference amplifier (AMP) 328. As with a HIB in a preferred embodiment of the present invention, a chopper-stabilized amplifier is used as a difference AMP to reduce DC offset voltage errors. A first signal input of the first difference AMP 328 is connected to the signal output of the first AC coupling capacitance element 312 and a second signal input of the first difference AMP 328 is connected to the signal output of the second AC coupling capacitance element 316 (i.e., through the third selectable shunt 322). The arrangement of the third and fourth selectable shunts 322, 324 causes the first difference AMP 328 to amplify the sum of its signal inputs when the switchable e-field sensing apparatus 300 is in its non-directional e-field sensing mode and to amplify the difference of its signal inputs when the switchable e-field sensing apparatus 300 is in its directional e-field sensing mode.

A signal output of the first difference AMP 328 is connected in parallel with a DC blocking capacitance element 330 (i.e., a third AC coupling capacitance element) and a phase compensation element 332. The DC blocking capacitance element 330 blocks the DC component of the output signal from the first difference AMP 328 and allows the AC component of the output signal from the first difference AMP 328 to pass. The phase compensation element 332 passes the DC component of the output signal from the first difference AMP 328 and adjusts the phase of the AC component of the output signal of the first difference AMP 328 to be equal to the phase change caused by the DC blocking capacitance element 330.

A first signal input of a second difference amplifier (AMP) 334 is connected to the signal output of the DC blocking capacitance element 330 and a second signal input of the second difference AMP 334 is connected to the signal output of phase change element 332. The second difference amplifier 334 amplifies the difference between the signals at its two inputs. This operation cancels the AC component of the signal at the output of the first difference AMP 328 and amplifies only the DC component of the output signal from the first difference AMP 328. A fifth selectable shunt 329 is connected between the phase compensation element 332 and the first difference AMP 328. The fifth selectable shunt 329 inhibits signal flow through the phase compensation element 332 when the switchable e-field sensing apparatus 300 is in its AC field sensing mode.

A signal output of the second difference AMP 334 is coupled in parallel with a signal input of a sixth selectable shunt 336 and a signal input of a seventh selectable shunt 338. A band pass filtering element 340 is connected between a signal output of the sixth selectable shunt 336 and a signal input of a signal amplifier (AMP) 342. A signal rectifying element 344 is connected between a signal output of the signal amplifier 342 and an eighth selectable shunt 346. A signal output of the eighth selectable shunt 346 is connected to a signal output of the seventh selectable shunt 338. The band pass filtering element 340, the signal AMP 342, and the signal rectifying element 344 define an AC signal processing path between the sixth and eighth selectable shunts 336, 346.

The sixth, seventh and eighth selectable shunts 336, 338, 346 are each connected to the field current type selector 320. Through such connections, the field current type selector 320 allows the sixth, seventh and eighth selectable shunts 336, 338, 346 to be selectively controlled for actuating the AC field sensing mode and the DC field sensing mode of the switchable e-field sensing apparatus 300. When the sixth and eighth selectable shunts 336, 346 are in a condition where conductivity therethrough is provided and the seventh selectable shunt 338 is in a condition where conductivity therethrough is inhibited (i.e., the AC field sensing mode discussed above), the AC signal processing path between the sixth and eighth selectable shunts 336, 346 is active (i.e., continuity therethrough is provided) and the bypass path around the AC signal processing path is disabled (i.e., continuity therethrough is inhibited). When the sixth and eighth selectable shunts 336, 346 are in a condition where conductivity therethrough is inhibited and the seventh selectable shunt 338 is in a condition where conductivity therethrough is provided (i.e., the DC field sensing mode discussed above), the AC signal processing path between the sixth and eighth selectable shunts 336, 346 is inactive (i.e., continuity therethrough is inhibited) and the bypass path around the AC signal processing path is enabled (i.e., continuity therethrough is provided).

The band pass filtering element 340 is configured for allowing an AC signal having a particular frequency range (e.g., between about 50 and 60 Hertz) to pass, thereby eliminating any extraneous AC noise signals. The signal AMP 342 amplifies AC signal proved thereto from the band pass filtering element 340. The signal rectifying element 344 provides a DC output signal from the AC input signal provided thereto from the signal AMP 342. The DC output signal is proportional to the strength of the AC input signal.

A first signal input of a voltage comparator (VC) 348 is connected to both the signal output of the seventh selectable shunt 338 and to the signal output of the eighth selectable shunt 346, thereby allowing the VC 348 to receive an input signal at its first signal input from the signal rectifying element 344 when the switchable e-field sensing apparatus 300 is in the AC field sensing mode and to receive an input signal at its first signal input from the second AMP 334 when the switchable e-field sensing apparatus 300 is in the DC field sensing mode. A DC voltage reference 349 is connected to a second signal input of the VC 348, thereby allowing a time/temperature stabilized threshold limit voltage to be provided to the VC 348. In this manner, the VC 348 compares the field-derived signal at its first signal input to the DC reference voltage 349 at its second signal input. When the voltage of the field-derived signal (i.e., the processed e-field signal) exceeds the DC reference voltage 349, an output signal of the VC 348 causes output of an e-field indicating signal by an e-field indicating device 350. Signals provided to the e-field indicating device 350 are referred to herein as processed e-field signals (i.e., a processed AC e-field signal or a processed DC e-field signal). Examples of alert signals by the e-field indicating device 350 include, but are not limited to, an audible alert signal, a visual alert signal, a tactile alert, an electric discrete/analog alert signal, an intelligent protocol communication signal wired or wireless or any combination of alert signals. Furthermore, the e-field indicating signal can be configured in a manner that indicates a relative magnitude of the sensed e-field. The components of the apparatus 300 that are connected between the sensor 302 and the e-field indicating device 350 are an embodiment of sensor signal processing circuitry configured in accordance with the present invention.

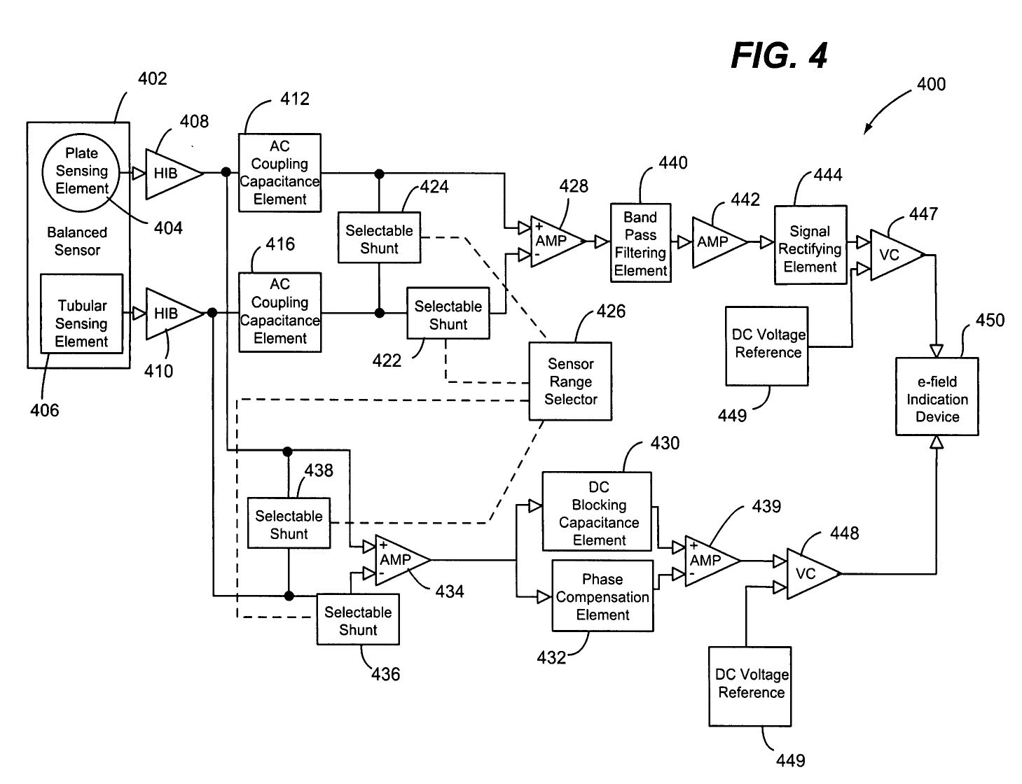

Referring now to FIG. 4, a block diagram of an apparatus configured in accordance with an embodiment of the present invention for simultaneously performing AC e-field sensing and DC e-field sensing (i.e., simultaneous e-field sensing apparatus 400) is shown. Circuitry of the simultaneous e-field sensing apparatus 400 provides an indication as to whether an AC e-field and/or DC e-field is present within proximity to the e-field sensing apparatus 400.

A balanced e-field sensor 402 is provided for interacting with a DC e-field and/or an AC e-field when immersed therein. The balanced e-field sensor 402 has a plate sensing element 404 and a tubular sensing element 406. In this regard, the balanced e-field sensor 402 is preferably, but not necessarily, of a similar construction of the same construction as that disclosed above in reference to the balanced e-field sensor 100 of FIGS. 1A and 1B. Accordingly, the balanced e-field sensor 402 is configured for coupling to an e-field toward the front of the plate sensing element 404, thereby providing for directional sensing of e-fields, and is configured for coupling to an e-field surrounding the tubular sensing element 406, thereby providing for non-directional sensing of e-fields.

A first high impedance buffer (HIB) 408 has its signal input connected to the plate sensing element 404 and a second high impedance buffer (HIB) 410 has its signal input connected to the tubular sensing element 406. The first and second HIBs 408, 410 each convert high impedance of the balanced e-field sensor 402 to lower impedance required to drive circuitry downstream of the first and second HIBs 408, 410. It is disclosed herein that the signal input of the first and second HIBs 408, 410 can each be connected to the respective sensing element 404, 406 through a resistive element arrangement discussed above in reference to signal input of the HIB 204 in FIG. 2. To this end, it is disclosed herein that the sensing elements 404, 406 are each connected to the respective HIB 408, 410 in a manner that provides a required voltage characteristic at the respective HIB signal input.

With respect to an AC e-field sensing circuit path of the simultaneous e-field sensing apparatus 400, a signal output of the first HIB 408 is connected to a first AC coupling capacitance element 412 and a signal output of the second HIB 410 is connected to a second AC coupling capacitance element 416. Through a first selectable shunt 422, a second selectable shunt 424, and a sensor range selector 426, the simultaneous e-field sensing apparatus 400 is configured for being selectively switchable between a mode for non-directional (e.g., omni-directional) e-field sensing and directional (e.g., a direction that the e-field sensing apparatus 400 is pointing). The first selectable shunt 422 is provide in series with an signal output of the second AC coupling capacitance element 416 and the second selectable shunt 424 is provided in parallel between the signal outputs of the first AC coupling capacitance element 412 and the second AC coupling capacitance element 416. As mentioned above, non-directional e-field sensing can be useful in determining that a potentially dangerous voltage source is present and directional e-field sensing can be useful in determining where a source of the potentially dangerous voltage source is located. Thus, the ability to selectively switch between such non-directional and directional e-field sensing modes is useful.

The sensor range selector 426 allows the first and second selectable shunts 422, 424 to be selectively controlled for causing the switchable e-field sensing apparatus 400 to be selectively switched between its non-directional e-field sensing mode and its directional e-field sensing mode. When the sensor range selector 426 is configured for causing non-directional e-field sensing to be provided, the first selectable shunt 422 is in an open configuration and the second selectable shunt 424 is in a closed configuration. When the sensor range selector 426 is configured for causing directional e-field sensing to be provided, the first selectable shunt 422 is in a closed configuration and the second selectable shunt 424 is in an open configuration. As mentioned above, within the context of the present invention, a selectable shunt allows for conductivity therethrough when in its closed configuration and inhibits conductivity therethrough when in its open configuration.

The first and second selectable shunts 422, 424 are connected between the first and second AC coupling capacitance elements 412, 416 and a first difference amplifier (AMP) 428. A first signal input of the first difference AMP 428 is connected to the signal output of the first AC coupling capacitance element 412 and a second signal input of the first difference AMP 428 is connected to the signal output of the second AC coupling capacitance element 416 (i.e., through the first selectable shunt 422). The arrangement of the first and second selectable shunts 422, 424 causes the first difference AMP 428 to amplify the sum of its signal inputs when the switchable e-field sensing apparatus 400 is in its non-directional e-field sensing mode and to amplify the difference of its signal inputs when the switchable e-field sensing apparatus 400 is in its directional e-field sensing mode.

A band pass filtering element 440 is connected between a signal output of the first difference AMP 428 and a signal input of a signal amplifying element (AMP) 442. An output of the signal AMP 442 is connected to a signal input of a signal rectifying element 444. The band pass filtering element 440 is configured for allowing an AC signal having a particular frequency range (e.g., between about 50 and 60 Hertz) to pass, thereby eliminating any extraneous AC noise signals. The signal AMP 442 amplifies AC signal provided thereto from the band pass filtering element 440. The signal rectifying element 444 provides a DC output signal from the AC input signal provided thereto from the signal AMP 442. The DC output signal is proportional to the strength of the AC input signal.

A first signal input of a first voltage comparator (VC) 447 is connected to a signal output of the signal rectifying element 444. A DC reference voltage 449 is connected to a second signal input of the first VC 447, thereby allowing a time/temperature stabilized threshold limit voltage to be provided to the first VC 447. In this manner, the first VC 447 compares the field-derived signal at its first signal input to the DC reference voltage 449 at its second signal input. When the voltage of the field-derived signal exceeds the DC reference voltage 449, an output signal of the first VC 447 causes output of an e-field indicating signal by an e-field indicating device 450. Examples of alert signals by the e-field indicating device 450 include, but are not limited to, an audible alert signal, a visual alert signal, a tactile alert, an electric discrete/analog alert signal, an intelligent protocol communication signal wired or wireless or any combination of alert signals. Furthermore, the e-field indicating signal can be configured in a manner that indicates a relative magnitude of the sensed e-field.

With respect to a DC e-field sensing circuit path of the simultaneous e-field sensing apparatus 400, a signal output of the first HIB 408 is connected to a first signal input of a second difference amplifier (AMP) 434 and a signal output of the second HIB 410 is connected to a second signal input of the second difference AMP 434 through a third selectable shunt 436. A fourth selectable shunt 438 is connected in parallel between the signal output of the first HIB 408 and the signal output of the second HIB 410. Through the selectable shunts 422, 424, 436, 438 and a sensor range selector 426, the simultaneous e-field sensing apparatus 400 is configured for being selectively switchable between a mode for non-directional (e.g., omni-directional) e-field sensing and a mode for directional e-field sensing (e.g., a direction that the e-field sensing apparatus 400 is pointing). When the sensor range selector 426 is configured for causing directional e-field sensing to be provided, the third selectable shunt 436 is in a closed configuration and the fourth selectable shunt 438 is in an open configuration. As mentioned above, non-directional e-field sensing can be useful in determining that a potentially dangerous voltage source is present and directional e-field sensing can be useful in determining where a source of the potentially dangerous voltage source is located. Thus, the ability to selectively switch between such non-directional and directional e-field sensing modes is useful.

The arrangement of the third and fourth selectable shunts 436, 438 causes the second difference AMP 434 to amplify the sum of its signal inputs when the switchable e-field sensing apparatus 400 is in its non-directional e-field sensing mode and to amplify the difference of its signal inputs when the switchable e-field sensing apparatus 400 is in its directional e-field sensing mode. A signal output of the second difference AMP 434 is connected in parallel with a DC blocking capacitance element 430 (i.e., a third AC coupling capacitance element) and a phase compensation element 432. The DC blocking capacitance element 430 blocks the DC component of the output signal from second difference AMP 434 and allow the AC component of the output signal from the second difference AMP 434 to pass. The phase compensation element 432 passes the DC component of the output signal from the second difference AMP 434 and adjusts the phase of the AC component of the output signal of the second difference AMP 434 to be equal to the phase change caused by the DC blocking capacitance element 430.

A first signal input of a third difference amplifier (AMP) 439 is connected to the signal output of the DC blocking capacitance element 430 and a second signal input of the third difference AMP 439 is connected to the signal output of phase change element 432. The third difference AMP 439 amplifies the difference between the signals at its two inputs. This operation cancels the AC component of the signal at the output of the second difference AMP 434 and amplifies only the DC component of the output signal from the second difference AMP 434.

A first signal input of a second voltage comparator (VC) 448 is connected to a signal output of the third difference AMP 439. A DC voltage reference 449 (or another DC reference voltage) is connected to a second signal input of the second VC 448, thereby allowing a time/temperature stabilized threshold limit voltage to be provided to the second VC 448. In this manner, the second VC 448 compares the field-derived signal at its first signal input to the DC reference voltage 449 at its second signal input. When the voltage of the field-derived signal exceeds the DC reference voltage, an output signal of the second VC 448 causes output of an e-field indicating signal by an e-field indicating device 450. Signals provided to the e-field indicating device 450 are referred to herein as processed e-field signals (i.e., a processed AC e-field signal or a processed DC e-field signal). In this manner, it is disclosed herein that the e-field indicating device 450 is configured for allowing separate inputs to cause output of an e-field indicating signal therefrom (i.e., the AC Voltage comparator output signal and the DC Voltage comparator output signal can be combined to provide a common alarm in addition to separate indications for the two signal types). For example, the e-field indicating device 450 can include circuitry that causes output of an e-field indicating signal in response to alert triggering signalling from the AC e-field sensing circuit path and/or from the DC e-field sensing circuit path. Examples of alert signals by the e-field indicating device 450 include, but are not limited to, an audible alert signal, a visual alert signal, a tactile alert, an electric discrete/analog alert signal, an intelligent protocol communication signal wired or wireless or any combination of alert signals. Furthermore, the e-field indicating signal can be configured in a manner that indicates a relative magnitude of the sensed e-field. Still further, it is disclosed herein that a DC e-field sensitivity adjustor (e.g., adjustable DC reference voltage) can be implemented in certain embodiments of the present invention. The components of the apparatus 400 that are connected between the sensor 402 and the e-field indicating device 450 are an embodiment of sensor signal processing circuitry configured in accordance with the present invention.

It is disclosed herein that e-field detection circuitry configured in accordance with the present invention (e.g., those discussed above in reference to FIGS. 2-4) can advantageously utilize one or more forms of AC field reduction techniques. Specifically, by reducing the AC Field effects associated with nearby power and/or communication systems, an e-field detection apparatus or system incorporating such e-field detection circuitry can be made more accurate and sensitive to the e-fields produced by objects of interest. Examples of such AC field reduction techniques include, but are not limited to, AC field cancellation and AC zero cross.

AC field cancellation can be used to effectively negate the multiplicity of AC frequencies in an area around an e-field sensing apparatus configured for sensing a DC e-field. The DC and AC field effects can be gathered and fed into front (i.e., primary) amplifiers of the e-field sensing apparatus. This signal is referred to herein as the main field signal. The main field signal will also be fed into a secondary filter path used to strip off an AC component of the main field signal and invert this AC signal component. This inverted AC signal component is then summed back with the main field signal resulting in the negation of the AC field component from the main field signal. This technique will work when multiple AC frequencies are present by allowing the e-field sensing apparatus to cancel the varied AC signal inputs seen at its front end.

AC zero cross can be used to sample a DC/AC field signal at the front end portion of the e-field sensing apparatus circuitry for helping to eliminate the AC field component from the DC/AC field signal (i.e., from the main field signal). By effectively sampling the incoming AC field and detecting the zero voltage cross point, an e-field sensing apparatus configured in accordance with the present invention (i.e., circuitry thereof) can be triggered to sample the combined DC/AC field signal when the AC is at a minimum level. This technique will reduce the effect of AC Field on the e-field sensing apparatus circuitry.

It is also disclosed herein that suitable oscillation and/or modulation techniques can be used for sensing a DC field in a manner that would allow for noise reduction benefits of an AC amp. These types of techniques refer to a process known as synchronous demodulation, which is used in circuits such as lock-in amplifiers. A lock-in amplifier works by synchronously detecting a carrier modulated output of the signal source. Because the desired signal information is contained within the carrier, the system constitutes an extremely narrow-band amplifier. Non-carrier related components of the signal are rejected and the amplifier passes only signals that are coherent with the carrier. In practice, lock-in amplifiers can extract a signal about 120 dB below the noise level. Accordingly, synchronous demodulation can be used for modulating the output of an e-field sensor configured in accordance with the present invention (e.g., the balanced e-field sensor 100 discussed above in reference to FIGS. 1A and 1B.

Presented now is a discussion relating to applications for and use of an e-field sensing apparatus configured in accordance with the present invention. High DC voltage is often utilized for powering certain system components and/or for carrying out power transmission between a power generation location and one or more locations where such power is utilized. Examples of such applications include, but are not limited to, fully electric and/or hybrid electric vehicles, utility company power transmission, solar panel arrays, vehicles in public transportation railway systems, and the like. The use of DC in automobiles and trucks has become increasingly popular. With voltages currently between 300 and 450 volts DC (VDC), accidents present a hazard to safety professionals trying to assist victims. The need for more energy and smaller sized batteries will trend toward even higher DC voltage (e.g., 1000 VDC or more) and more danger. The broadcast industry and other such industries that erect antenna masts, towers or other equipment utilize safety sensors to detect the presence of AC electric fields. However, the use of DC voltage transmission lines will make the present safety technology for detection of electrical lines ineffective. The use of DC voltage in small commuter trains, trams and streetcars can present a similar safety hazard. Still further, solar panels of solar electric systems can generate between 600 and 1000V DC, which is then transmitted to inverters to be converted to AC voltages for standard use in homes and businesses, thereby presenting the potential for a significant safety hazard.

Accordingly, it will be beneficial for an e-field sensing apparatus in accordance with an embodiment of the present invention to be suitably configured for use in these types of applications. To this end, it is disclosed herein that an e-field sensing apparatus configured in accordance with an embodiment of the present invention can be implemented in any number of possible arrangements. For certain types of applications, it will be advantageous and/or beneficial for such an e-field sensing apparatus to be implemented as a standalone handheld apparatus (e.g., a handheld e-field sensing unit configured for probing areas surrounding the unit) or at least partially integrated into an article of manufacture wearable by a user (e.g., a glove, boot, or passive safety monitor). For example, an emergency response personnel would find use in such a standalone handheld apparatus or wearable article of manufacture through which they can determine if a potentially dangerous HV DC e-field is present and optionally, if so, where a source of such HV DC e-field is located. In this manner, an apparatus configured in accordance with the present invention can be embodied as an article of manufacture. In other types of applications, it will be advantageous and/or beneficial for such an e-field sensing apparatus to be integrated into a system having a high DC voltage source (e.g., integrated with a safety, control, and/or communication module of a hybrid electric or fully-electric vehicle, a transit/railway car, a power distribution/transmission system, etc). For example, in a hybrid electric or fully-electric vehicle, an integrated HV DC e-field sensing apparatus could be coupled to a communication system for alerting a remote entity (e.g., a emergency responder or 911 operator) of a HV DC e-field in case of an accident, could be coupled to an electrical distribution system for disconnecting the high DC voltage source from power distribution circuitry in case of an accident, and/or could be coupled to a warning system for outputting an audible and/or visual warning if an unanticipated HV DC e-field is detected.

Hybrid electric and fully electric vehicles represent a preferred application for an e-field sensing apparatus configured in accordance with the present invention. It is disclosed herein that a plurality of discrete e-field sensing apparatuses can be integrated into body panels and/or a chassis of a vehicle for enabling continuous safety status checks to be provided to vehicle computers or other safety/communication systems (e.g., an on-board cellular/satellite communication system). These e-field sensing apparatuses could be powered by the vehicle's low voltage system with battery or other power backup within the sensing apparatuses to let them operate without vehicle power. Implementation of e-field sensing apparatuses in this manner would be beneficial in the event of an accident and/or in the case where a high voltage cable becomes cut or worn and shorted to the vehicle chassis in which case, the e-field sensing apparatus would cause the high DC voltage battery to be disconnected.

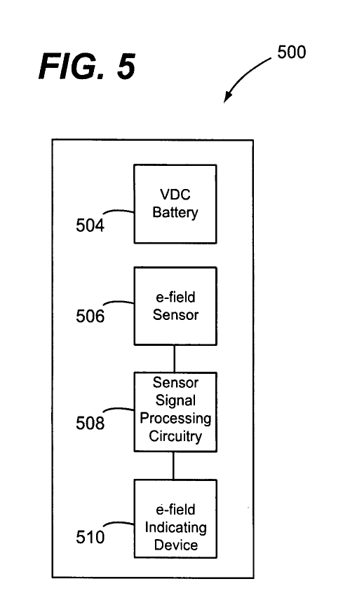

Accordingly, as shown in FIG. 5, a system 500 configured in accordance with an embodiment of the present invention can provide for sensing presence of an e-field generated by a DC voltage source of the system 500. The system comprises a battery 504 serving as the DC voltage source for electrical equipment of the system 500. An e-field sensor 506 is provided for sensing an e-field generated by the battery 504 and, optionally, electrical components connected to the battery 504. Sensor signal processing circuitry 508 is connected to the e-field sensor 506 for receiving a sensor output signal therefrom. An e-field indicating device 510 is coupled to the sensor signal processing circuitry 508 for receiving a processed DC e-field signal therefrom. The sensor 506 outputs the sensor output signal, which is dependent upon a distance between the sensor 506 and the battery 504 and/or a relative position of the e-field sensor 506 with respect to the battery 504. The sensor signal processing circuitry 508 derives a processed DC e-field signal from the sensor output signal. The e-field indicating device 510 outputs an e-field indicating signal in response to the processed DC e-field signal indicating that the e-field exceeds an e-field threshold level.

In the preceding detailed description, reference has been made to the accompanying drawings that form a part hereof, and in which are shown by way of illustration specific embodiments in which the present invention may be practiced. These embodiments, and certain variants thereof, have been described in sufficient detail to enable those skilled in the art to practice embodiments of the present invention. It is to be understood that other suitable embodiments may be utilized and that logical, mechanical, chemical and electrical changes may be made without departing from the spirit or scope of such inventive disclosures. To avoid unnecessary detail, the description omits certain information known to those skilled in the art. The preceding detailed description is, therefore, not intended to be limited to the specific forms set forth herein, but on the contrary, it is intended to cover such alternatives, modifications, and equivalents, as can be reasonably included within the spirit and scope of the appended claims.

What is claimed is:

1. An apparatus, comprising:
sensor signal processing circuitry having an input for receiving first and second sensor output signals from a sensor for sensing an electric field (e-field) generated by a voltage source, wherein said sensor signal processing circuitry outputs a processed alternating current (AC) e-field signal from said first and second sensor output signals when an AC e-field sensing mode of said sensor signal processing circuitry is enabled, wherein said sensor signal processing circuitry outputs a processed direct current (DC) e-field signal from said first and second sensor output signals when a DC e-field sensing mode of said sensor signal processing circuitry is enabled.

2. The apparatus of claim 1 wherein:
said processed AC and DC e-field signals are dependent upon the distance between the sensor and the voltage source substantially irrespective of the direction the sensor is pointing with respect to the voltage source when a non-directional e-field sensing mode of said sensor signal processing circuitry is enabled, and
said processed AC and DC e-field signals are dependent upon the relative direction the sensor is pointing with respect to the voltage source when a directional e-field sensing mode of said sensor signal processing circuitry is enabled.

3. The apparatus of claim 1 wherein:
the sensor includes a first e-field sensing element for providing the first sensor output signal and a second e-field sensing element for providing the second sensor output signal;
the first sensing element is disposed in an open space within the second sensing element;
a total surface area of the first e-field sensing element is approximately the same as a total surface area of the second e-field sensing element; and
an insulating material is situated between said first and second sensing elements thereby inhibiting electrical conductivity therebetween.

4. The apparatus of claim 3 wherein:
the first e-field sensing element is in the form of a flat plate;
the second e-field sensing element is in the form of a tube;
a planar face of the flat plate is substantially flush with an end face of the tube.

5. The apparatus of claim 4 wherein:
said processed AC and DC e-field signals are dependent upon the distance between the sensor and the voltage source substantially irrespective of the direction the sensor is pointing with respect to the voltage source when a non-directional e-field sensing mode of said sensor signal processing circuitry is enabled, and
said processed AC and DC e-field signals are dependent upon the relative direction the sensor is pointing with respect to the voltage source when a directional e-field sensing mode of said sensor signal processing circuitry is enabled.

6. The apparatus of claim 1, further comprising:
an e-field indicating device coupled to said sensor signal processing circuitry for receiving said processed e-field signals therefrom, wherein the e-field indicating device outputs an e-field indicating signal in response to at least one of said processed e-field signals indicating that the e-field exceeds a respective e-field threshold level.

7. The apparatus of claim 6 wherein:
said sensor signal processing circuitry includes an AC e-field sensing circuit path and a DC e-field sensing circuit path;
the AC e-field sensing circuit path and the DC e-field sensing circuit path are connected in parallel between the sensor and the e-field indication device for causing parallel processing of the processed AC e-field signal and the processed DC e-field signal.

8. The apparatus of claim 7 wherein:
said processed AC and DC e-field signals are dependent upon the distance between the sensor and the voltage source substantially irrespective of the direction the sensor is pointing with respect to the voltage source when a non-directional e-field sensing mode of said sensor signal processing circuitry is enabled, and
said processed AC and DC e-field signals are dependent upon the relative direction the sensor is pointing with respect to the voltage source when a directional e-field sensing mode of said sensor signal processing circuitry is enabled.

9. The apparatus of claim 7 wherein:
the sensor includes a first e-field sensing element for providing the first sensor output signal and a second e-field sensing element for providing the second sensor output signal;
the first sensing element is disposed in an open space within the second sensing element;
a total surface area of the first e-field sensing element is approximately the same as a total surface area of the second e-field sensing element; and
an insulating material is situated between said first and second sensing elements thereby inhibiting electrical conductivity therebetween.

10. An apparatus, comprising:
a sensor for sensing an electric field (e-field) generated by a DC voltage source, wherein the sensor outputs a sensor output signal that is dependent upon a proximity of the sensor with respect to the DC voltage source;
sensor signal processing circuitry connected to the sensor for receiving the sensor output signal therefrom, wherein said sensor signal processing circuitry outputs a processed direct current (DC) e-field signal from the sensor output signal; and
an e-field indicating device coupled to said sensor signal processing circuitry for receiving the processed DC e-field signal therefrom, wherein the e-field indicating device outputs an e-field indicating signal in response to the processed DC e-field signal indicating that the e-field exceeds an e-field threshold level.

11. The apparatus of claim 10 wherein:
the processed DC e-field signal is dependent upon the distance between the sensor and the voltage source substantially irrespective of the direction the sensor is pointing with respect to the voltage source when a non-directional e-field sensing mode of said sensor signal processing circuitry is enabled, and
the processed DC e-field signal is dependent upon the relative direction the sensor is pointing with respect to the voltage source when a directional e-field sensing mode of said sensor signal processing circuitry is enabled.

12. The apparatus of claim 10 wherein:
the sensor includes a first e-field sensing element for providing the first sensor output signal and a second e-field sensing element for providing the second sensor output signal;
the first sensing element is disposed in an open space within the second sensing element;
a total surface area of the first e-field sensing element is approximately the same as a total surface area of the second e-field sensing element; and
an insulating material is situated between said first and second sensing elements thereby inhibiting electrical conductivity therebetween.

13. The apparatus of claim 12 wherein:
the first e-field sensing element is in the form of a flat plate;
the second e-field sensing element is in the form of a tube;
a planar face of the flat plate is substantially flush with an end face of the tube.

14. The apparatus of claim 13 wherein:
the processed DC e-field signal is dependent upon the distance between the sensor and the voltage source substantially irrespective of the direction the sensor is pointing with respect to the voltage source when a non-directional e-field sensing mode of said sensor signal processing circuitry is enabled, and
the processed DC e-field signal is dependent upon the relative direction the sensor is pointing with respect to the voltage source when a directional e-field sensing mode of said sensor signal processing circuitry is enabled.

15. An apparatus, comprising:
a sensor for sensing an electric field (e-field) generated by a voltage source, wherein the sensor outputs a first sensor output signal that is dependent upon a distance between the sensor and the voltage source substantially irrespective of a direction the sensor is pointing with respect to the voltage source and simultaneously outputs a second sensor output signal that is dependent upon the relative direction the sensor is pointing with respect to the voltage source;
sensor signal processing circuitry connected to the sensor for receiving said first and second sensor output signals therefrom, wherein said sensor signal processing circuitry simultaneously outputs a processed alternating current (AC) e-field signal and a processed direct current (DC) e-field signal from said first and second sensor output signals; and
an e-field indicating device coupled to said sensor signal processing circuitry for receiving the processed AC e-field signal and the processed DC e-field signal therefrom, wherein the e-field indicating device outputs an e-field indicating signal in response to at least one of the processed AC e-field signal indicating that the e-field has an AC e-field portion that exceeds an AC e-field threshold level and the processed DC e-field signal indicating that the e-field has a DC e-field portion that exceeds a DC e-field threshold level.

16. The apparatus of claim 15 wherein:
said processed AC and DC e-field signals are dependent upon the distance between the sensor and the voltage source substantially irrespective of the direction the sensor is pointing with respect to the voltage source when a non-directional e-field sensing mode of said sensor signal processing circuitry is enabled, and
said processed AC and DC e-field signals are dependent upon the relative direction the sensor is pointing with respect to the voltage source when a directional e-field sensing mode of said sensor signal processing circuitry is enabled.

17. The apparatus of claim 15 wherein:
the sensor includes a first e-field sensing element for providing the first sensor output signal and a second e-field sensing element for providing the second sensor output signal;
the first sensing element is disposed in an open space within the second sensing element;
a total surface area of the first e-field sensing element is approximately the same as a total surface area of the second e-field sensing element; and
an insulating material is situated between said first and second sensing elements thereby inhibiting electrical conductivity therebetween.

18. The apparatus of claim 17 wherein:
the first e-field sensing element is in the form of a flat plate;
the second e-field sensing element is in the form of a tube;
a planar face of the flat plate is substantially flush with an end face of the tube.

19. The apparatus of claim 18 wherein:
said processed AC and DC e-field signals are dependent upon the distance between the sensor and the voltage source substantially irrespective of the direction the sensor is pointing with respect to the voltage source when a non-directional e-field sensing mode of said sensor signal processing circuitry is enabled, and
said processed AC and DC e-field signals are dependent upon the relative direction the sensor is pointing with respect to the voltage source when a directional e-field sensing mode of said sensor signal processing circuitry is enabled.

20. The apparatus of claim 15, further comprising:
an e-field indicating device coupled to said sensor signal processing circuitry for receiving said processed e-field signals therefrom, wherein the e-field indicating device outputs an e-field indicating signal in response to at least one of said processed e-field signals indicating that the e-field exceeds a respective e-field threshold level.

21. The apparatus of claim 20 wherein:
said sensor signal processing circuitry includes an AC e-field sensing circuit path and a DC e-field sensing circuit path;
the AC e-field sensing circuit path and the DC e-field sensing circuit path are connected in parallel between the sensor and the e-field indication device for causing parallel processing of the processed AC e-field signal and the processed DC e-field signal.

22. The apparatus of claim 21 wherein:
said processed AC and DC e-field signals are dependent upon the distance between the sensor and the voltage source substantially irrespective of the direction the sensor is pointing with respect to the voltage source when a non-directional e-field sensing mode of said sensor signal processing circuitry is enabled, and
said processed AC and DC e-field signals are dependent upon the relative direction the sensor is pointing with respect to the voltage source when a directional e-field sensing mode of said sensor signal processing circuitry is enabled.

23. The apparatus of claim 21 wherein:
the sensor includes a first e-field sensing element for providing the first sensor output signal and a second e-field sensing element for providing the second sensor output signal;
the first sensing element is disposed in an open space within the second sensing element;
a total surface area of the first e-field sensing element is approximately the same as a total surface area of the second e-field sensing element; and
an insulating material is situated between said first and second sensing elements thereby inhibiting electrical conductivity therebetween.

24. A system, comprising:
a battery serving as a DC voltage source for electrical equipment of the system;
a sensor for sensing an electric field (e-field) generated by the DC voltage source, wherein the sensor outputs a sensor output signal that is dependent upon a distance between the sensor and the DC voltage source;
sensor signal processing circuitry connected to the sensor for receiving the sensor output signal therefrom, wherein said sensor signal processing circuitry outputs a processed direct current (DC) e-field signal from the sensor output signal; and
an e-field indicating device coupled to said sensor signal processing circuitry for receiving the processed DC e-field signal therefrom, wherein the e-field indicating device outputs an e-field indicating signal in response to the processed DC e-field signal indicating that the e-field exceeds an e-field threshold level.

25. The system of claim 24 wherein:
the processed DC e-field signal is dependent upon the distance between the sensor and the voltage source substantially irrespective of the direction the sensor is pointing with respect to the voltage source when a non-directional e-field sensing mode of said sensor signal processing circuitry is enabled, and
the processed DC e-field signal is dependent upon the relative direction the sensor is pointing with respect to the voltage source when a directional e-field sensing mode of said sensor signal processing circuitry is enabled.

26. The system of claim 24 wherein:
the sensor includes a first e-field sensing element for providing the first sensor output signal and a second e-field sensing element for providing the second sensor output signal;
the first sensing element is disposed in an open space within the second sensing element;
a total surface area of the first e-field sensing element is approximately the same as a total surface area of the second e-field sensing element; and
an insulating material is situated between said first and second sensing elements thereby inhibiting electrical conductivity therebetween.

27. The system of claim 26 wherein:
the first e-field sensing element is in the form of a flat plate;
the second e-field sensing element is in the form of a tube;
a planar face of the flat plate is substantially flush with an end face of the tube.

28. The system of claim 27 wherein:
the processed DC e-field signal is dependent upon the distance between the sensor and the voltage source substantially irrespective of the direction the sensor is pointing with respect to the voltage source when a non-directional e-field sensing mode of said sensor signal processing circuitry is enabled, and
the processed DC e-field signal is dependent upon the relative direction the sensor is pointing with respect to the voltage source when a directional e-field sensing mode of said sensor signal processing circuitry is enabled.

29. A method, comprising:
sensing an electric field (e-field) generated by a voltage source, wherein said sensing includes generating at least one e-field characterizing signal corresponding to the e-field;
performing an alternating current (AC) e-field sensing mode of operation for deriving a processed AC e-field signal from said at least one e-field characterizing signal, wherein the processed AC e-field signal corresponds to an AC voltage level of the voltage source; and
performing a direct current (DC) e-field sensing mode of operation for deriving a processed DC e-field signal from at least one e-field characterizing signal, wherein the processed DC e-field signal corresponds to a DC voltage level of the voltage source.

30. The method of claim 29 wherein:
said processed AC and DC e-field signals are dependent upon the distance between the sensor and the voltage source substantially irrespective of the direction the sensor is pointing with respect to the voltage source when a non-directional e-field sensing mode of said sensor signal processing circuitry is enabled, and
said processed AC and DC e-field signals are dependent upon the relative direction the sensor is pointing with respect to the voltage source when a directional e-field sensing mode of said sensor signal processing circuitry is enabled.

31. The method of claim 29 wherein:
said sensing is performed using a sensor includes a first e-field sensing element for providing the first sensor output signal and a second e-field sensing element for providing the second sensor output signal;
the first sensing element is disposed in an open space within the second sensing element;
a total surface area of the first e-field sensing element is approximately the same as a total surface area of the second e-field sensing element; and
an insulating material is situated between said first and second sensing elements thereby inhibiting electrical conductivity therebetween.

32. The method of claim 31 wherein:
the first e-field sensing element is in the form of a flat plate;
the second e-field sensing element is in the form of a tube;
a planar face of the flat plate is substantially flush with an end face of the tube.

33. The method of claim 32 wherein:
said processed AC and DC e-field signals are dependent upon the distance between the sensor and the voltage source substantially irrespective of the direction the sensor is pointing with respect to the voltage source when a non-directional e-field sensing mode of said sensor signal processing circuitry is enabled, and
said processed AC and DC e-field signals are dependent upon the relative direction the sensor is pointing with respect to the voltage source when a directional e-field sensing mode of said sensor signal processing circuitry is enabled.

34. The method of claim 31, further comprising:
providing said processed e-field signals to an e-field indicating device; and
outputting an e-field indicating signal from the an e-field indicating device in response to at least one of said processed e-field signals indicating that the e-field exceeds a respective e-field threshold level.

35. The method of claim 34 wherein:
performing the AC e-field sensing mode of operation includes providing at least one e-field characterizing signal to an AC e-field sensing circuit path;
performing the DC e-field sensing mode of operation includes providing at least one e-field characterizing signal to an DC e-field sensing circuit path; and
the AC e-field sensing circuit path and the DC e-field sensing circuit path are connected in parallel between the sensor and the e-field indication device for causing parallel processing of the processed AC e-field signal and the processed DC e-field signal.
